(19) United States
(12) Patent Application Publication
(10) Pub. No.: US 2025/0287663 A1
(43) Pub. Date: Sep. 11, 2025

(54) INTEGRATED CIRCUIT CHIP COMPRISING A RADIOFREQUENCY COMPONENT

(71) Applicant: STMicroelectronics International N.V., Geneva (CH)

(72) Inventors: Frederic Gianesello, Saint Jeoire Prieuré (FR); Siddhartha Dhar, Delhi (IN)

(21) Appl. No.: 19/056,066

(22) Filed: Feb. 18, 2025

(30) Foreign Application Priority Data
Mar. 7, 2024 (FR) FR2402317

(51) Int. Cl. H10D 62/17; H01L 21/761; H01L 21/762; H10D 86/00; H10D 86/01

(52) U.S. Cl. CPC H10D 62/371; H01L 21/761; H01L 21/76243; H10D 86/01; H10D 86/201

(57) ABSTRACT

The present description concerns an integrated circuit chip comprising at least one component, arranged inside and/or on top of a structure comprising a semiconductor substrate on which rests an insulating layer having a semiconductor layer resting thereon, wherein at least two PN junctions are arranged at the interface between the substrate and the insulating layer.

### CROSS REFERENCE TO RELATED APPLICATIONS

This application claims the priority benefit of French Patent Application No. 2402317, filed on Mar. 7, 2024, entitled “Circuit intégré comprend un composant radiofréquence,” which is hereby incorporated herein by reference to the maximum extent allowable by law.

### TECHNICAL FIELD

The present disclosure generally concerns the field of integrated circuit chips and their manufacturing processes. It more specifically aims at the field of integrated circuit chips comprising a radio frequency component and their manufacturing methods.

### BACKGROUND

One generally calls radio frequency components as components intended to use AC electrical signals at frequencies in the range from 3 kHz to 30 GHz. Among known radio frequency components, active components such as amplifiers, mixers, and data converters, and passive components such as capacitors, inductors, and antennas can be found.

It would be desirable to be able to improve, at least partly, certain aspects of integrated circuit chips comprising a radio frequency component.

### SUMMARY

There exists a need for electronic components formed on a better electrically insulated SOI-type structure.

There exists a need for integrated circuit chips intended for radio frequency applications comprising such electronic components.

There exists a need for methods of manufacturing such electronic components.

An embodiment overcomes all or part of the disadvantages of known electronic components.

An embodiment overcomes all or part of the disadvantages of known integrated circuit chips intended for radio frequency applications.

An embodiment overcomes all or part of the disadvantages of known methods of manufacturing such chips.

An embodiment provides an electronic component formed inside and on top of an SOI-type structure in which PN junctions are formed at the interface between the support substrate and the buried oxide layer.

An embodiment provides an integrated circuit chip comprising such an electronic chip.

An embodiment provides a method of manufacturing such an electronic component.

An embodiment provides an integrated circuit chip comprising at least one component, arranged inside and/or on top of a structure comprising a semiconductor substrate on which rests an insulating layer having a semiconductor layer resting thereon, wherein at least two PN junctions are arranged at the interface between the substrate and the insulating layer.

According to an embodiment, the at least two PN junctions are arranged against the interface between the substrate and the insulating layer.

According to an embodiment, the PN junctions comprise an alternation of N-type doped wells and of P-type doped wells.

According to an embodiment, the N-type doped wells have a width greater than or equal to 78 nm.

According to an embodiment, the P-type doped wells have a width greater than or equal to 200 nm.

According to an embodiment, the semiconductor substrate has a resistivity greater than 125 ohm·cm.

According to an embodiment, the component is a switch.

According to an embodiment, the component is a MOS-type transistor.

According to an embodiment, the chip is adapted to radio frequency applications, the component being intended to use AC electrical signals at frequencies in the range from 3 kHz to 30 GHz.

According to an embodiment, the chip is an SPDT-type switch, the component being a switch.

According to an embodiment, the chip is a radio frequency switch with a frequency band selection, the component being a switch.

Another embodiment provides a method of manufacturing an integrated circuit chip comprising at least one component, and being formed inside and/or on top of a structure comprising a semiconductor substrate on which rests an insulating layer having a semiconductor layer resting thereon, the method comprising a step of forming of at least two PN junctions formed at the interface between the substrate and the insulating layer.

According to an embodiment, the step of forming of the at least two PN junctions comprises the following steps:
a first masking step;
a first step of implantation of P-type dopants at the interface between the substrate and the insulating layer to form P-type doped wells;
a second masking step;
a second step of implantation of N-type dopants at the interface between the substrate and the insulating layer to form N-type doped wells; and
an anneal step.

According to an embodiment, the P-type dopants comprise boron.

According to an embodiment, the N-type dopants comprise arsenic.

According to an embodiment, the anneal step is a thermal ramp step performed by a laser.

According to an embodiment, the method comprises, after the step of forming of the at least two PN junctions, a step of manufacturing of the component.

According to an embodiment, the component is formed from the semiconductor layer.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows a cross-section view of an embodiment of an integrated circuit chip;

FIG. 2 illustrates a step of an implementation mode of a method of manufacturing the embodiment of FIG. 1;

FIG. 3 illustrates another step of an implementation mode of a method of manufacturing the embodiment of FIG. 1;

FIG. 4 illustrates another step of an implementation mode of a method of manufacturing the embodiment of FIG. 1;

FIG. 5 illustrates another step of an implementation mode of a method of manufacturing the embodiment of FIG. 1;

FIG. 6 illustrates another step of an implementation mode of a method of manufacturing the embodiment of FIG. 1;

FIG. 7 illustrates another step of an implementation mode of a method of manufacturing the embodiment of FIG. 1;

FIG. 8 illustrates another step of an implementation mode of a method of manufacturing the embodiment of FIG. 1;

FIG. 9 shows an embodiment of a chip comprising the embodiment of FIG. 1;

FIG. 10 shows an example of the chip of FIG. 9; and

FIG. 11 shows another example of the chip of FIG. 9.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

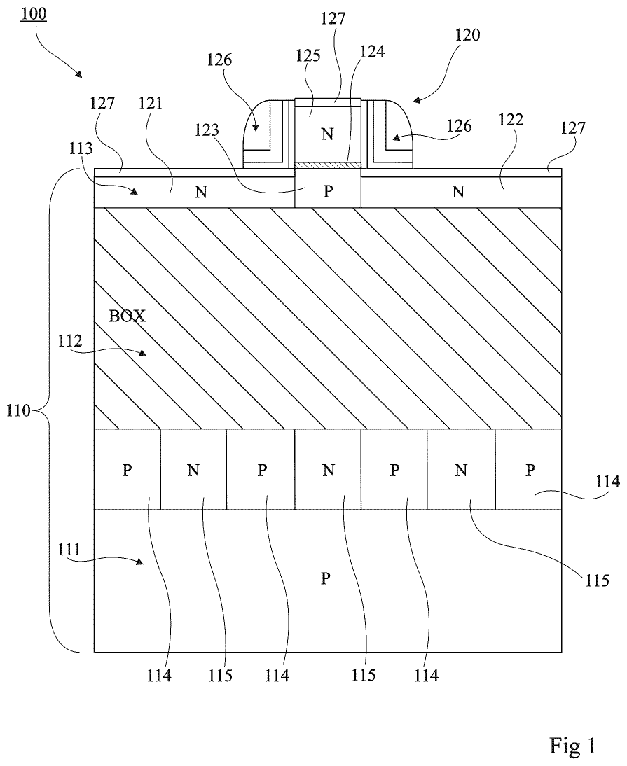

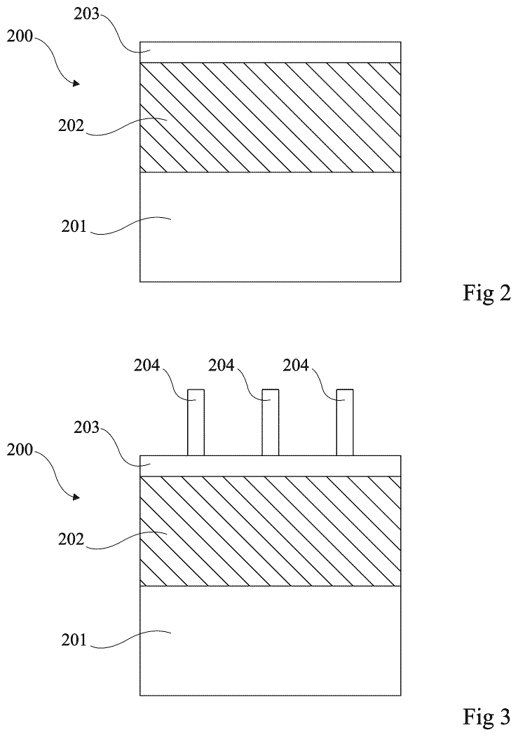

The embodiments described hereafter concern the electrical insulation of electronic chips, and more particularly the electrical insulation of integrated circuit chips adapted to receiving radio frequency signals, that is, AC electrical signals having a frequency in the range from 3 kHz to 30 GHz. The components in question herein are chips formed inside and/or on top of a structure of substrate-on-insulator type, or SOI-type structure. Leakage currents may happen to cross the insulating layer at the entrance of the SOI structure by capacitive effect, it is thus important to correctly insulate such chips. A way enabling to overcome this problem is to form PN junctions at the interface between the buried insulating layer and the support substrate of the SOI-type structure. An electronic chip formed inside and/or on top of such a structure is described in relation with FIG. 1, and a method of manufacturing such a chip is described in relation with FIGS. 2 to 8.

Further, the embodiments described hereafter are particularly adapted to being used in integrated circuit chips used for radio frequency applications, that is, for applications using radio frequency signals. Examples of application of the embodiments are described in relation with FIGS. 9 to 11.

FIG. 1 is a cross-section view of an integrated circuit chip 100 formed inside and/or on top of an SOI-type structure 110 and comprising at least one electronic component 120.

The structure of SOI type 110 (Substrate On Insulator) comprises a stack comprising:
a semiconductor substrate 111 (P), also called support substrate 111;
a buried insulating layer 112 (BOX) resting on top of and in contact with an upper surface of support substrate 111; and
a semiconductor layer 113 resting on top of and in contact with an upper surface of buried insulating layer 112, opposite to a lower surface of insulating layer 112 in contact with the upper surface of support substrate 111.

Support substrate 111 is a substrate made of a semiconductor material, that is, of a material comprising one or a plurality of elements from column 14 of the periodic table of elements, such as silicon or germanium. According to a preferred embodiment, support substrate 111 is a high-resistivity substrate, that is, a substrate having a resistivity greater than or equal to 125 ohm·cm.

Buried layer 112 is an electrically-insulating layer having a thickness generally in the range from 10 to 400 nm, preferably from 200 to 400 nm. According to an embodiment, layer 112 is made of silicon oxide.

Semiconductor layer 113 is a layer made of a material comprising one or a plurality of elements from column 14 of the periodic table of elements, such as silicon or germanium. According to an example, semiconductor layer 113 has a thickness generally in the range from 40 nm to 500 μm, preferably in the range from 40 nm to 3 μm.

According to an embodiment, the SOI structure further comprises insulation enabling to prevent charge leakages from components formed based on semiconductor layer 113 into buried insulating layer 112 by capacitive effect. This insulation includes the forming of PN junctions at the interface between support substrate 111 and buried insulating layer 112. For this purpose, an alternation of P-type 114 (P) and N-type 115 (N) doped wells is formed at this interface. According to an embodiment, SOI structure 110 comprises at least two PN junctions formed at this interface, preferably more than 5 PN junctions, for example in the order of at least some ten PN junctions. In FIG. 1, in order not to overload the drawing, 6 PN junctions are shown. An implementation mode of a method of manufacturing such an SOI structure is described in detail in relation with FIGS. 2 to 8.

More specifically, there is here called alternation of N-type doped wells 114 and of P-type doped wells 115 a succession of wells 114 and 115 in which each well 114 is surrounded by two wells 115, and each well 115 is surrounded by two wells 114. Thereby, PN junctions, as illustrated in FIG. 1, are formed along the interface between substrate 111 and buried insulating layer 112.

According to an embodiment, wells 114 are portions of support substrate 111 extending from its upper surface, which are P-type doped. In other words, wells 114 have been doped by using one or a plurality of chemical elements forming part of column 13 of the periodic table of elements, such as boron. According to an example, wells 114 have a minimum thickness of 3 μm, and a minimum width of 200 nm. According to an example, well 114 comprises a concentration of dopant elements in the range from 10¹⁸ cm⁻³ to 10²⁰ cm⁻³, for example in the order of 10¹⁹ cm⁻³.

According to an embodiment, wells 115 are portions of support substrate 111 extending from its upper surface which are N-type doped. In other words, wells 115 have been doped by using one or a plurality of chemical elements forming part of column 15 of the periodic table of elements, such as arsenic. According to an example, wells 115 have a minimum thickness of 3 μm, and a minimum width of 78 nm, for example in the range from 78 nm to 5 μm. According to an example, well 114 comprises a concentration of dopant elements in the range from 10¹⁸ cm⁻³ to 10²⁰ cm⁻³, for example in the order of 10¹⁹ cm⁻³.

In the example of FIG. 1, electronic component 120 is a switch, such as a switch adapted to receiving radio frequency signals, that is, signals having a frequency in the range from 3 kHz to 30 GHz. More particularly, in the example of FIG. 1, component 120 is a metal-oxide-semiconductor field-effect transistor, or MOSFET transistor, or MOS transistor. In addition, component 120 is an N-channel MOS transistor, or N-type MOS transistor, or NMOS transistor.

Component 120, or transistor 120, is formed from semiconductor layer 113. Transistor 120 comprises an N-doped source region 121 (N), formed across the entire thickness of a portion of semiconductor layer 113 (on the left-hand side in FIG. 1), and an N-doped drain region 122 (N), formed across the entire thickness of another portion of semiconductor layer 113 (on the right-hand side in FIG. 1). Regions 121 and 122 are separated by a P-doped channel region 123 (P). Channel region 123 is formed across the entire thickness of a portion of semiconductor layer 113 (at the center in FIG. 1).

Component 120 further comprises a gate stack comprising a gate insulator layer 124 formed on an upper surface of channel region 123, and a gate layer 125 (N) resting on top of and contacting gate insulator layer 123. Layers 124 and 125 have a width in the order of the width of channel region 123.

Component 120 further comprises spacers 126 enabling to protect the lateral surfaces of the gate stack. Examples of spacers are illustrated in FIG. 1 and are within the abilities of those skilled in the art. In FIG. 1, spacers 126 comprise three insulating layers resting one on top of the other.

Component 120 further comprises silicide layers 127 arranged on an upper surface of source 121 and drain 122 regions and on an upper surface of gate layer 125.

An advantage of the embodiment illustrated in FIG. 1 is that it enables to avoid charge leakages in buried insulating layer 112.

FIGS. 2 to 9 are cross-section views illustrating steps of an implementation mode of a method of manufacturing a device of the type of the device 100 described in relation with FIG. 1.

At the step of FIG. 2, an SOI structure 200 of the type of the SOI structure 110 described in relation with FIG. 1 is considered. Structure 200 thus comprises:
a semiconductor support substrate 201 of the type of the support substrate 111 described in relation with FIG. 1;
a buried insulating layer 202 of the type of the buried insulating layer 112 described in relation with FIG. 1, layer 202 resting on top of and in contact with support substrate 202; and
a semiconductor layer 203 of the type of the semiconductor layer 113 described in relation with FIG. 1, layer 203 resting on top of and in contact with buried insulating layer 202 on a surface opposite to support substrate 201.

At the step of FIG. 3, a mask 204 is formed on an upper surface of semiconductor layer 203, opposite to the surface of semiconductor layer 203 in contact with buried insulating layer 202. Mask 204 enables to define the width of P-type doped wells of the type of the wells 114 described in relation with FIG. 1. According to an example, mask 204 is formed by a photolithography step.

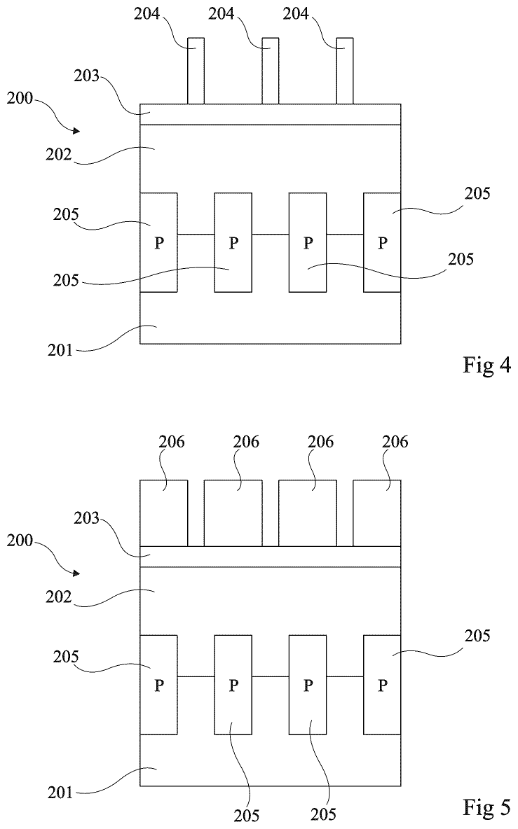

At the step of FIG. 4, P-type doping elements are deeply implanted into the structure 200 of FIG. 3. More specifically, these doping elements form P-type doped wells 205 at the interface between buried insulating layer 202 and support substrate 201. These wells 205 may extend over a portion of insulating layer 202 and a portion of support substrate 201. According to an embodiment, the doping elements here are chemical elements forming part of column 13 of the periodic table of elements. According to an example, the doping elements comprise boron.

In the step of FIG. 5, mask 204 is removed from the upper surface of semiconductor layer 203.

Further, at the step of FIG. 5, a mask 206 is formed on an upper surface of semiconductor layer 203, opposite to the surface of semiconductor layer 203 in contact with buried insulating layer 202. Mask 206 enables to define the width of N-type doped wells of the type of the wells 115 described in relation with FIG. 1. According to an example, mask 206 is formed by a photolithography step.

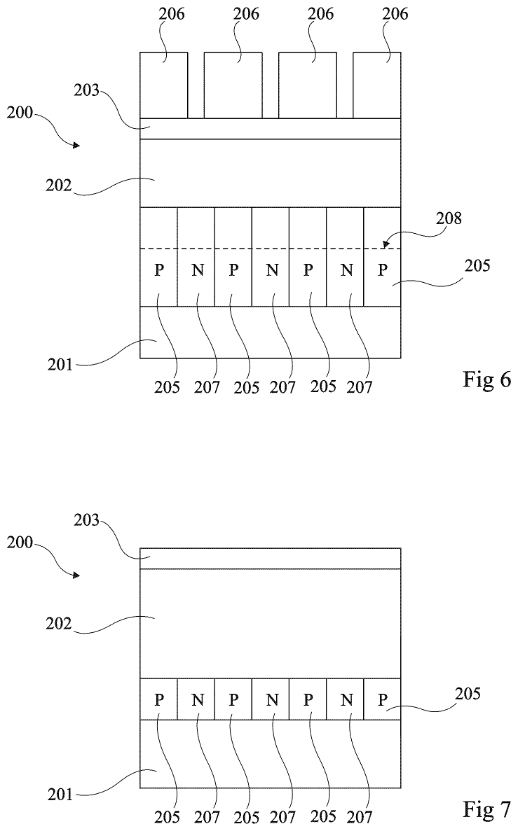

At the step of FIG. 6, N-type dopant elements are deeply implanted into the structure 200 of FIG. 5. More specifically, these doping elements form N-type doped wells 207 at the interface between buried insulating layer 202 and support substrate 201, designated in FIG. 6 by a dotted line 208. These wells 207 may extend over a portion of insulating layer 202 and a portion of support substrate 201. According to an embodiment, the doping elements here are chemical elements forming part of column 15 of the periodic table of elements. According to an example, the doping elements comprise arsenic.

According to an embodiment, and as shown in relation with FIG. 1, the P-type 205 and N-type 207 doped wells are arranged alternately. More specifically, each well 204 is surrounded by two wells 205, and each well 205 is surrounded by two wells 204. Thereby, PN junctions, as illustrated in FIG. 6, are formed along the interface between substrate 201 and buried insulating layer 202. To obtain such a result, masks 204 and 206 have periodic openings in opposition with respect to each other.

At the step of FIG. 7, an annihilation operation is implemented. This step enables to make layer 202 insulating again. According to an example, the annihilation operation is a heat treatment step, for example an anneal step or a thermal ramp step. According to a specific example, the annihilation operation is a thermal ramp step carried out by a laser, with a temperature varying between 500 and 600° C.

The step of FIG. 7 enables to migrate the doping elements present in buried insulating layer 202 and, more generally, to decrease the thickness of wells 205 and 207.

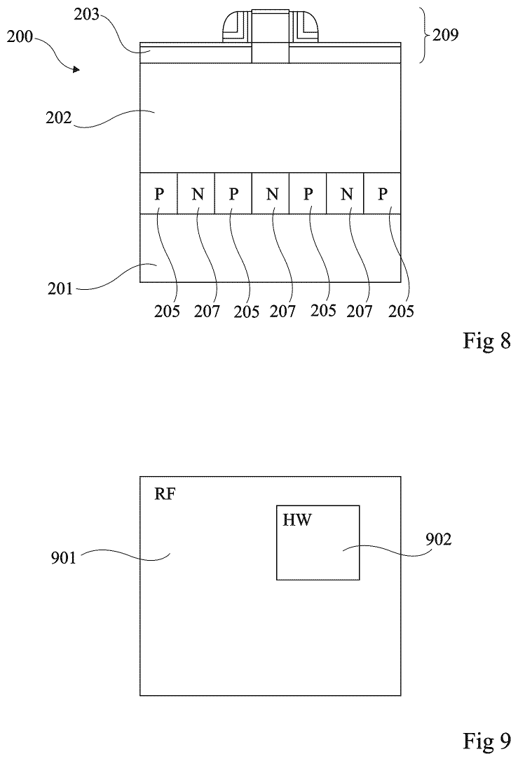

At the step of FIG. 8, a component 209, of the type of component 120, is formed from semiconductor layer 203. The steps of manufacturing such a component are within the abilities of those skilled in the art.

According to an embodiment, the dimensions of wells 205 and 207 are established according to the different stages of manufacturing of component 209. Indeed, the steps of manufacturing of component 209 may comprise heat treatment operations capable of having the doping elements of the wells 205 and 507 diffuse, and this phenomenon is to be avoided. This is why wells 207 have a minimum thickness of 3 μm, and a minimum width of 200 nm, and wells 207 have a minimum thickness of 3 μm, and a minimum width of 78 nm. In practice, wells 207 have a width much greater than 78 nm, for example in the order of several hundreds of nm.

FIG. 9 shows an example of an integrated circuit chip 901 (RF) of the type of the integrated circuit chip 100 described in relation with FIG. 1.

As previously mentioned, an application of the chip 100 described in relation with FIG. 1 may be an integrated circuit chip formed on an SOI structure of the type of the structure 110 described in relation with FIG. 1, an earlier version of which comprises problems of current leakage in the buried insulating layer of the structure.

More particularly, integrated circuit chip 901 represents a preferred application of the chip 100 of FIG. 1, since chip 901 is adapted to using radio frequency signals. More precisely, chip 901 comprises at least one electronic component 902 (HW) of the type of the component 120 described in relation with FIG. 1, adapted to using one or a plurality of radio frequency signals. As previously described, component 902 may be any electronic component adapted to processing one or a plurality of radio frequency signals, such as a switch, a transmission line, or an integrated inductor.

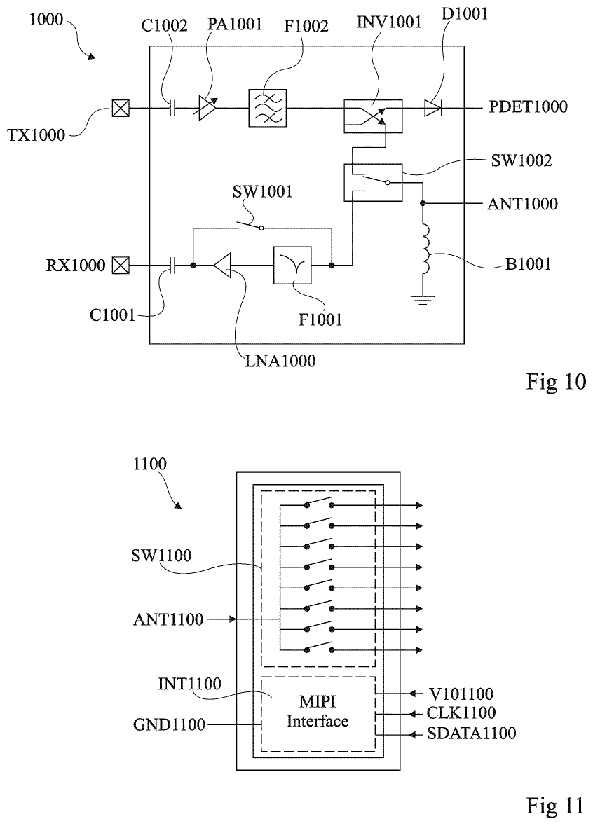

FIG. 10 shows another example of an integrated circuit chip 1000 of the type of the integrated circuit chip 100 described in relation with FIG. 1.

Integrated circuit chip 1000 is a switch or relay of SPDT (Single Pole Double Throw) type intended to be controlled by radio frequency signals, for example signals using home WiFi communication protocols.

According to an example, integrated circuit chip 1000 comprises an input node RX1000 and an output node TX1000 adapted, respectively, to receiving and to transmitting radio frequency signals.

Integrated circuit chip 1000 further comprises a connection to an antenna ANT1000, and a connection PDET100 enabling to collect an image of the output power of the antenna. This image is obtained by using a signal sampled from a directional coupler INV1001 described hereafter.

Integrated circuit chip 1000 comprises, on a first branch of reception of a signal by the antenna, a capacitor C1001, an amplifier LNA1000, a filtering circuit F1001, and a switch SW1001. A first conduction terminal of capacitor C1001 is coupled, preferably connected, to input node RX1000, and a second conduction terminal of capacitor C1001 is coupled, preferably connected, to an output of amplifier LNA1000. An input of amplifier LNA1000 is coupled, preferably connected, to an output of filtering circuit F1001. According to an example, amplifier LNA1000 is a low-noise amplifier. Switch SW1001 is arranged in parallel with amplifier LNA1000 and with filtering circuit F1001. More particularly, a conduction terminal of switch SW1001 is coupled, preferably connected, to the output of amplifier LNA1000, and a second conduction terminal of switch SW1001 is coupled, preferably connected, to an input of filtering circuit F1001.

Integrated circuit chip 1000 further comprises a switch SW1002, having an input coupled, preferably connected, to antenna ANT1000 and comprising two outputs. A first output is coupled to the first branch and, more precisely, is coupled, preferably connected, to the input of filtering circuit F1001. A second output is coupled to a second transmission branch of the chip 1000 described hereafter.

Integrated circuit chip 1000 further comprises a coil B1001 coupling antenna ANT1000 to a terminal receiving a reference potential, for example the ground. Thus, a first terminal of coil B1001 is coupled, preferably connected, to antenna ANT1001, and a second terminal of coil B1001 is coupled, preferably connected, to the node receiving the reference potential.

Integrated circuit chip 1000 further comprises a second branch for transmitting signals to antenna ANT1000, comprising a capacitor C1002, an amplifier PA1001, a filtering circuit F1002, directional coupler INV1001, and a diode D1001. A first conduction terminal of capacitor C1002 is coupled, preferably connected, to input node TX1000, and a second conduction terminal of capacitor C1002 is coupled, preferably connected, to an input of amplifier PA1001. An output of amplifier PA1001 is coupled, preferably connected, to an output of filter circuit F1002. According to an example, amplifier PA1001 is a controllable-gain amplifier. An input of inverter IV1001 is coupled, preferably connected, to the output of filter circuit F1002. A first output of coupler INV1001 is coupled, preferably connected, to the second output of switch SW1002, and a second output of coupler INV1001 is coupled, preferably connected, to an anode of diode D1001. Directional coupler INV1001 enables to sample a fraction of the signal arriving at the antenna, to be able to determine an image of the power level emitted by this antenna. The cathode of diode D1001 is coupled, preferably connected, to connection PDET100.

According to an example, switch SW1002 may be the component 120 described in relation with FIG. 1.

FIG. 11 shows another example of an integrated circuit chip 1100 of the type of the integrated circuit chip 100 described in relation with FIG. 1.

Integrated circuit chip 1100 is a radio frequency switch with a frequency band selection.

Integrated circuit chip 1100 comprises a control interface INT1100 (MIPI Interface) and a set of switches SW1100.

Interface INT1100 is adapted to controlling the set of switches SW1100 and receives, for this purpose, a communication signal VIO1100, a clock signal CLK1100, and a data signal SDATA1100. Interface INT1100 is further coupled to a reference potential, for example ground GND1100.

The set of switches SW1100 comprises N switches, N being an integer greater than one, all having a common input coupled to an antenna ANT1100, and distinct outputs. More particularly, each switch of set SW1100 has a first conduction terminal coupled, preferably connected, to antenna ANT1100, and a second conduction terminal coupled, preferably connected, to an output of set SW1100. In the example illustrated in FIG. 11, the set comprises eight (8) switches.

According to an example, the set of switches SW1100 may be the component 120 described in relation with FIG. 1.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

What is claimed:

1. An integrated circuit chip comprising:
a silicon-on-insulator structure comprising:
a semiconductor substrate;
an insulating layer disposed on the semiconductor substrate; and
a semiconductor layer disposed on the insulating layer;
at least two PN junctions disposed at an interface between the semiconductor substrate and the insulating layer; and
at least one component, arranged inside and/or on top of the silicon-on-insulator structure.

2. The integrated circuit chip according to claim 1, wherein the at least two PN junctions are disposed against the interface between the semiconductor substrate and the insulating layer.

3. The integrated circuit chip according to claim 1, wherein the at least two PN junctions comprise an alternation of N-type doped wells and of P-type doped wells.

4. The integrated circuit chip according to claim 3, wherein the N-type doped wells have a width greater than or equal to 78 nm.

5. The integrated circuit chip according to claim 3, wherein the P-type doped wells have a width greater than or equal to 200 nm.

6. The integrated circuit chip according to claim 1, wherein the semiconductor substrate has a resistivity greater than 125 ohm·cm.

7. The integrated circuit chip according to claim 1, wherein the at least one component is at least one switch.

8. The integrated circuit chip according to claim 7, wherein the at least one component is at least one metal-oxide-semiconductor (MOS)-type transistor.

9. The integrated circuit chip according to claim 1, wherein the at least one component is configured to use alternating current (AC) electrical signals at frequencies in a range from 3 kHz to 30 GHz.

10. The integrated circuit chip according to claim 9, wherein the integrated circuit chip is a single-pole double-throw (SPDT)-type switch, and the at least one component is at least one switch.

11. The integrated circuit chip according to claim 9, wherein the integrated circuit chip is a radio frequency switch with a frequency band selection, and the at least one component is at least one switch.

12. The integrated circuit chip according to claim 1, wherein the at least two PN junctions comprise more than five PN junctions.

13. A method of manufacturing an integrated circuit chip, the method comprising:
providing a silicon-on-insulator structure comprising:
a semiconductor substrate;
an insulating layer disposed on the semiconductor substrate; and
a semiconductor layer disposed on the insulating layer;
forming at least two PN junctions at an interface between the semiconductor substrate and the insulating layer; and
forming at least one component inside and/or on top of the silicon-on-insulator structure.

14. The method according to claim 13, wherein the forming the at least two PN junctions comprises:
forming a first mask on the silicon-on-insulator structure;
implanting P-type dopants at the interface between the semiconductor substrate and the insulating layer to form P-type doped wells;
forming a second mask on the silicon-on-insulator structure;
implanting N-type dopants at the interface between the semiconductor substrate and the insulating layer to form N-type doped wells; and
annealing the integrated circuit chip.

15. The method according to claim 14, wherein the P-type dopants comprise boron.

16. The method according to claim 14, wherein the N-type dopants comprise arsenic.

17. The method according to claim 14, wherein the annealing comprises a thermal ramp using by a laser.

18. The method according to claim 13, further comprising forming the at least one component after forming the at least two PN junctions.

19. The method according to claim 18, further comprising forming the at least one component at least in part using the semiconductor layer.

20. The method according to claim 13, wherein forming the at least two PN junctions comprises forming more than five PN junctions.
